(19) United States
(12) Patent Application Publication
(10) Pub. No.: US 2025/0273506 A1
(43) Pub. Date: Aug. 28, 2025

(54) SUBSTRATE SUPPORT WITH SENSOR

(71) Applicant: Applied Materials, Inc., Santa Clara, CA (US)

(72) Inventors: Jian LI, Fremont, CA (US); Juan Carlos ROCHA-ALVAREZ, San Carlos, CA (US); Jennifer Y. SUN, Mountain View, CA (US)

(21) Appl. No.: 18/586,104

(22) Filed: Feb. 23, 2024

(51) Int. Cl. H01L 21/687; H01L 21/67

(52) U.S. Cl. CPC H01L 21/68785; H01L 21/67248; H01L 21/68757

(57) ABSTRACT

A substrate support assembly is provided including: a shaft; and a substrate support including: a substrate support body attached to the shaft, the substrate support body formed of a first material; and a tube positioned inside the substrate support body, the tube formed of a second material having a melting point that is higher than a sintering temperature of the first material.

### BACKGROUND

### Field

Embodiments of the present disclosure generally relate to improved components (e.g., substrate supports) for use in process chambers, such as semiconductor process chambers, and methods of manufacturing the improved components.

### Description of the Related Art

Substrate supports in process chambers (e.g., semiconductor process chambers) often include one or more sensors to perform measurements used for controlling the process (e.g., deposition) performed in the process chamber. For example, substrate supports often include one or more temperature sensors inside the substrate support. In some embodiments, the temperature sensors can be used to control heat provided to the substrate support. The temperature sensors (e.g., thermocouples) are connected to one or more wires or leads routed through the interior of the substrate support and through a shaft that can be used to rotate the substrate support. Positioning a sensor in the interior of the substrate support can be challenging and/or expensive, especially when the sensor is to be located near the outer edge of the substrate support inside the substrate support. Current methods generally include forming separate plates with cavities to be used for placement of the sensor and then diffusion bonding the plates together. Diffusion bonding can be an expensive process.

Accordingly, improved substrate supports and processes for forming improved substrate supports with one or more sensors positioned inside the substrate support and near the outer edge of the substrate support is needed.

### SUMMARY

Embodiments of the present disclosure generally relate to improved components (e.g., substrate supports) for use in process chambers, such as semiconductor process chambers, and methods of manufacturing the improved components.

In one embodiment, a substrate support assembly is provided comprising: a shaft; and a substrate support comprising: a substrate support body attached to the shaft, the substrate support body formed of a first material; and a tube positioned inside the substrate support body, the tube formed of a second material having a melting point that is higher than a sintering temperature of the first material.

In another embodiment, a method for forming a substrate support is provided comprising: embedding a tube in a sintering material, an interior of the tube substantially devoid of the sintering material; performing a sintering process on the sintering material with the tube embedded in the sintering material to form a substrate support body; and inserting a sensor into the interior of the tube after performing the sintering process.

In another embodiment, a method for forming a substrate support is provided comprising: forming a first plate by performing a first sintering process on a first sintering material, the first plate having a first side and an opposing second side, wherein the first sintering process partially sinters the first sintering material; forming a second plate by performing a second sintering process on a second sintering material, the second plate having a first side and an opposing second side, wherein the second plate includes a recess on the first side and the second sintering process partially sinters the second sintering material; placing a powder inside the recess; positioning the first plate on top of the first side of the second plate, wherein a region between the first plate and recess of the second plate forms a cavity; and performing a third sintering process on the first plate and the second plate to join the first plate to the second plate and form a substrate support body having a top, a bottom, and one or more sides connecting the top to the bottom, wherein the powder is formed of a material having a higher melting point than a temperature of the sintering material during the third sintering process to join the first plate to the second plate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 shows a processing system, according to one embodiment.

FIGS. 2A-2C show different stages of a method for forming the substrate support assembly from FIG. 1, according to one embodiment.

FIG. 3 is a process flow diagram of a method for forming the substrate support assembly of FIG. 1, according to one embodiment.

FIGS. 4A-4D show different stages of forming an alternative substrate support assembly, according to one embodiment.

FIG. 5 is a process flow diagram of a method for forming the alternative substrate support assembly, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to improved substrate supports or other components for use in process chambers, such as semiconductor process chambers, and improved methods of manufacturing the improved components. The improvements generally relate to forming a void before sintering the material (e.g., aluminum nitride) that forms the body of the substrate support. In one embodiment, a tube is embedded in sintering material before a sintering process is performed. The tube can be formed of a material (e.g., molybdenum) having a melting point that is higher than the temperature at which the sintering process is performed. The interior of the tube can then be easily accessed after the sintering process by drilling a hole from the bottom of the substrate support to the interior of the tube. A flexible sensor can then easily be positioned in the tube to underlie an edge region of the substrate during processing. In another embodiment, two partially sintered plates are joined together in an additional sintering process to form a substrate support. A recess on a side of one of the partially sintered plates is used to form a cavity between the two plates when the two plates are sintered together. The cavity can then be easily accessed after the sintering process by drilling a hole from the bottom of the substrate support to the interior of the cavity. A flexible sensor can then easily be positioned in the cavity to underlie an edge region of the substrate during processing.

By having the void in the tube or the cavity accessible for positioning a sensor after the substrate support body is sintered in these two embodiments, the additional step of diffusion bonding sintered components (e.g., plates) is avoided. Conventional practice has been to fully sinter two separate plates and then join the plates together in a diffusion bonding process, where the plates are configured to form a void for insertion of a sensor after the diffusion boding process. Diffusion bonding can be an expensive and time consuming process. The methods disclosed herein avoid this costly diffusion bonding process for forming the substrate support body.

Although the following disclosure mainly describes improved methods for forming substrate supports with internal sensors, the methods can be more generally applied to form other components used in process chambers, such as electrostatic chucks, showerheads, or other components that are exposed to harsh process conditions while including internal devices, such as sensors.

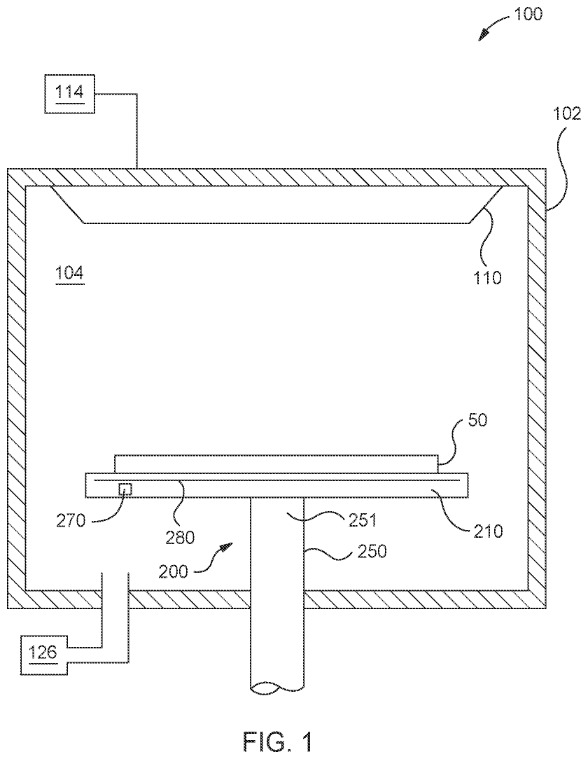

FIG. 1 shows a processing system 100, according to one embodiment. The processing system 100 includes a process chamber 101, a gas supply system 114, and a vacuum pump 126. The process chamber 101 includes a chamber body 102 enclosing an interior volume 104. In one embodiment, the process chamber 101 is a deposition chamber. In other embodiments, the process chamber 101 can include additional components (not shown) to perform other processes, such as a plasma deposition or etching process.

The process chamber 101 can include a showerhead 110 for directing process gases into the interior volume 104 of the process chamber 101. The vacuum pump 126 can be used to exhaust gases from the interior volume 104 and to maintain a specified pressure in the interior volume 104 during processing.

The process chamber 101 further includes a substrate support assembly 200 having a substrate support body 210 positioned in the interior volume 104. A substrate 50 can be positioned on the substrate support body 210 during processing, such as a deposition. The substrate support assembly 200 further includes a shaft 250 coupled to the substrate support body 210. The shaft 250 can be coupled to an actuator (not shown), which can rotate the shaft 250 during processing. The rotation of the shaft 250 can be used to rotate the substrate support body 210 and the substrate 50 positioned on the substrate support body 210 during processing. The rotation of the substrate 50 can improve process uniformity for the process (e.g., deposition) being performed on the substrate 50.

The substrate support assembly 200 can further include a heater 280 (e.g., a resistive heater) and a sensor 270, such as a temperature sensor (e.g., a thermocouple). The sensor 270 can be positioned in an outer region of the substrate support body 210 (i.e., a region not overlying the shaft 250). As described in further detail below, the sensor 270 can include one or more leads or wired connections routed through an interior 251 of the shaft 250 of the substrate support assembly 200.

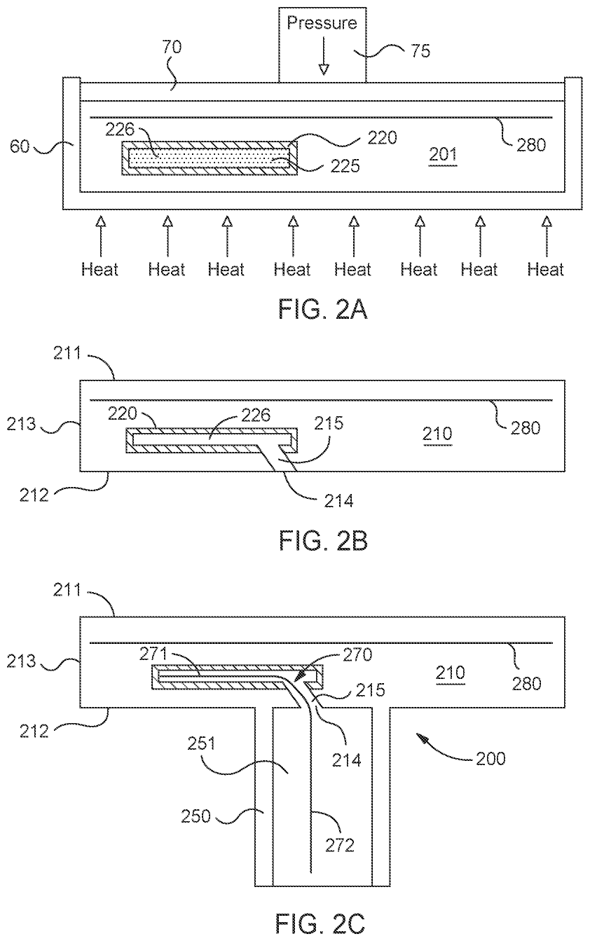

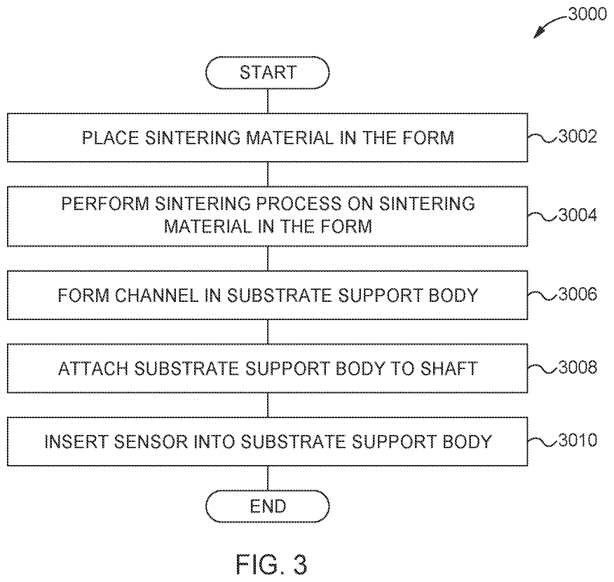

FIGS. 2A-2C show different stages of a method for forming the substrate support assembly 200 from FIG. 1, according to one embodiment. FIG. 3 is a process flow diagram of a method 3000 for forming the substrate support assembly of FIG. 1, according to one embodiment. The method 3000 is described in reference to FIGS. 2A-2C and FIG. 3.

The method 3000 begins at block 3002. At block 3002, with reference to FIG. 2A, sintering material 201 is placed in a form 60. The sintering material 201 is generally a ceramic material. In one embodiment, the sintering material 201 is aluminum nitride. The heater 280 is embedded in the sintering material 201. The heater 280 can include one or more conductors (not shown) that extend out of the bottom of the sintering material, so that electrical power can be provided to the heater 280 after the substrate support assembly 200 is installed in a process chamber. A tube 220 is also embedded in the sintering material 201. In some embodiments, the tube 220 is embedded in the sintering material 201 at a position below the heater 280. In some embodiments, the tube 220 can be formed of a material having a high melting point, such as a metal (e.g., molybdenum). For example, the material that the tube 220 is formed of can have a high melting point, such as a melting point that is at least 50° C. higher than the temperature used to perform the sintering process on the sintering material 201 during block 3004 described below. Used herein, a tube generally refers to a structure that fully or partially encloses an interior hollow region. In some embodiments, the tube 220 can be sealed (e.g., capped) at both ends, so that no sintering material enters the tube 220 during the sintering process.

Furthermore, in some embodiments, an interior 226 of the tube 220 can be filed with a powder 225. The powder 225 can provide structural support for the tube 220 during the sintering process. The powder 225 can also be formed of a material having a high melting point, such as a melting point that is at least 50° C. higher than the temperature used to perform the sintering process on the sintering material 201 during block 3004. In some embodiments, the tube 220 and the powder 225 can each be formed of a material having a melting point that is at least 50° C. higher than the melting point of the material used to form the substrate support body (i.e., the sintering material 201). In some embodiments, the powder 225 can be formed of one or more of carbon, molybdenum, and tungsten. Alternatively, in some embodiments, the interior of the tube 220 is empty during the sintering process during block 3004. The interior 226 of the tube 220 can be substantially devoid of sintering material 201 during the sintering process, such as less than 5% of the volume of the interior 226 being filled with sintering material 201 during the sintering process.

At block 3004, with reference to FIG. 2A, a sintering process is performed on the sintering material 201 in the form 60. The sintering process is performed with the tube 220 embedded in the sintering material 201. The sintering process forms the substrate support body 210 as shown in FIG. 2B. The substrate support body 210 includes a top 211, a bottom 212, and one or more side surfaces 213 connecting the bottom 212 with the top 211.

The sintering process can be performed at a high temperature and a high pressure. In one embodiment, heat is applied to increase the temperature of the sintering material to around 2000° C. Furthermore, in one embodiment, a shaft 75 can lower a plate 70 to apply high pressure to the top of the sintering material 201, such as a pressure greater than 100 bar, to press the sintering material 201 against the form 60 during the sintering process.

At block 3006, with reference to FIG. 2B, a channel 215 can be machined (e.g., drilled) into the substrate support body 210. The channel 215 can extend from an opening 214 in the bottom 212 of the substrate support body 210 to the interior 226 of the tube 220. After the channel 215 is formed, the powder 225 can be removed (e.g., vacuumed out) from the interior 226 of the tube 220 through the channel 215. Alternatively, in some embodiments, the powder 225 can be burned off at a relatively low temperature, for example at atmospheric pressure, to remove the powder 225 from the interior 226 of the tube 220. Alternatively, in some embodiments, the tube 220 can include an additional portion (not shown) that can extend to the bottom 212 of substrate support body 210, which can reduce the amount of effort, such as machining (e.g., drilling) used to access the interior 226 of the tube 220.

At block 3008, with reference to FIG. 2C, the substrate support body 210 is attached to the shaft 250. In some embodiments, the substrate support body 210 is diffusion bonded to the shaft 250.

At block 3010, with reference to FIG. 2C, the sensor 270 is positioned in the interior 226 of the tube 220. The sensor 270 can be flexible and can be inserted into the interior 226 of the tube 220 through the interior 251 of the shaft 250 and then through the channel 215 of the substrate support body 210 that connects the interior 251 of the shaft 250 to the interior 226 of the tube 220. The sensor 270 can include a sensing portion 271 that is positioned at location in the interior 226 of the tube 220 that does not overlie the interior 251 of the shaft 250. For example, the sensing portion 271 can be positioned to underlie an outer zone (e.g., edge region) of the substrate 50 (see FIG. 1) during processing. The sensor 270 can further include one or more connectors 272 (e.g., wires) that extend through the interior 251 of the shaft 250 and electrically connect the sensing portion 271 to another device, such as a controller (not shown) that can receive measurements from the sensor 270 during processing.

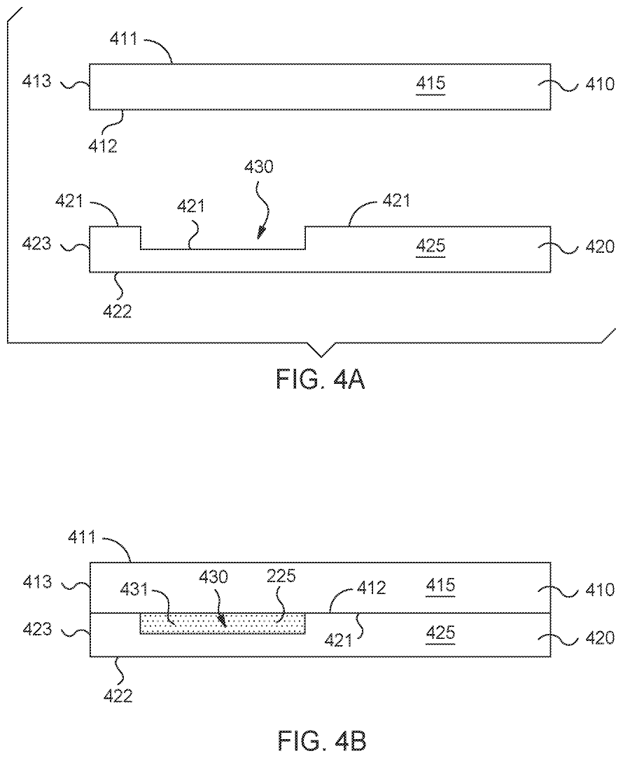

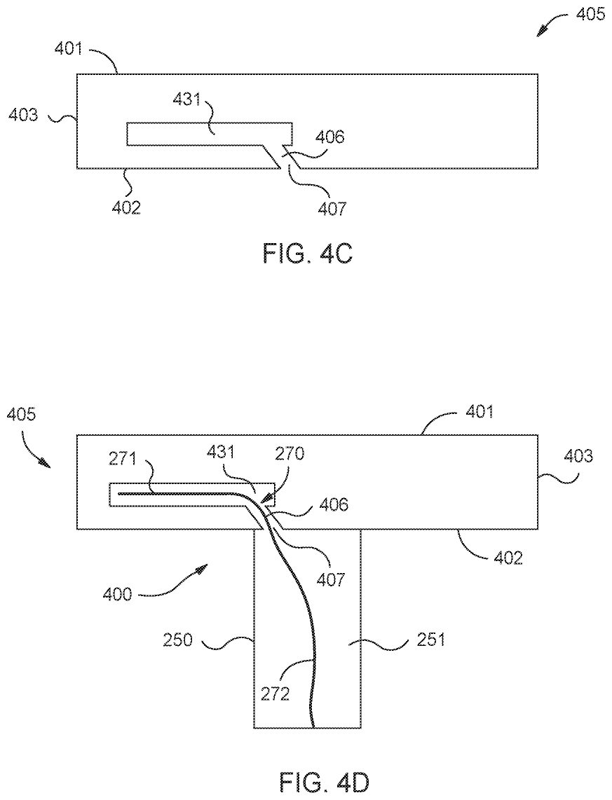

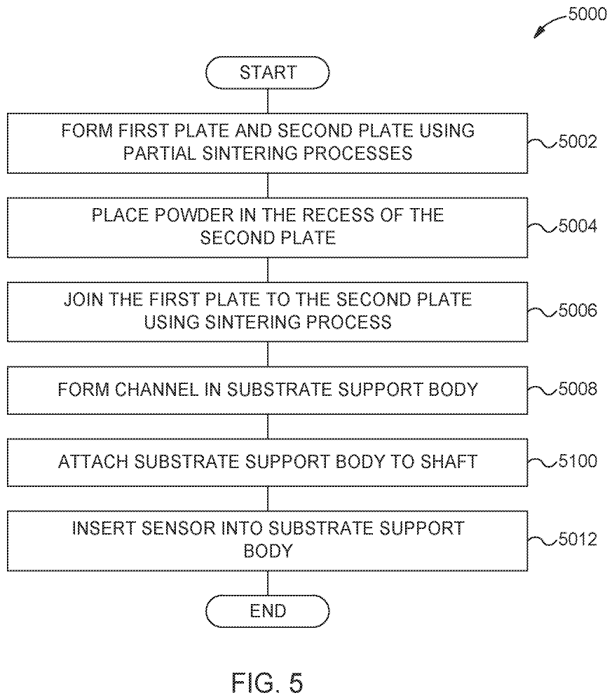

FIGS. 4A-4D show different stages of forming an alternative substrate support assembly 400, according to one embodiment. FIG. 5 is a process flow diagram of a method 5000 for forming the substrate support assembly 400, according to one embodiment. The method 5000 is described in reference to FIGS. 4A-4D and FIG. 5.

The method 5000 begins at block 5002. At block 5002 with reference to FIG. 4A, a first plate 410 is formed by performing a first sintering process on a first sintering material 415, and a second plate 420 is formed by performing a second sintering process on a second sintering material 425. The first sintering material 415 and the second sintering material 425 are generally formed of a ceramic material, such as aluminum nitride. The first sintering process and the second sintering process can generally be performed as described above in reference to FIG. 2A, for example by applying heat and pressure to the sintering material after placing the sintering material in a form, such as the form 60 shown in FIG. 2A. Although the first and second sintering processes can each be similar to the sintering process described above in reference to FIG. 2A, the first and second sintering processes only partially sinter the first sintering material 415 and the second sintering material 425. In some embodiments, the first and second sintering processes can be (1) performed for less time and/or (2) performed at lower temperatures and/or pressures than would otherwise be required to more fully sinter the corresponding first sintering material 415 and the second sintering material 425. Used herein, partial sintering can refer to a sintering process in which the end product of the partial sintering process can be further sintered to reduce to the volume of the end product by at least another 10%, such as by at least another 25% without losing any significant mass. For example, the first plate 410 is formed by a partial sintering process at block 5002, and the volume of the first plate 410 can be reduced by at least another 10% or at least by another 25% in a subsequent sintering process, such as the process described below in reference to block 5006 when the first plate 410 is joined with the second plate 420.

The first plate 410 can include a first side 411 and an opposing second side 412 with one or more sidewalls 413 connecting the first side 411 with the second side 412. Similarly, the second plate 420 can include a first side 421 and an opposing second side 422 with one or more sidewalls 423 connecting the first side 421 with the second side 422. The first side of 421 of the second plate 420 can include a recess 430 that can be used to create the space that is subsequently used to insert the sensor 270 into the substrate support body 405 as described in more detail below. Although not shown, the first plate 410 or the second plate 420 can include the heater 280 shown in FIG. 1.

At block 5004, with reference to FIG. 4B, the powder 225 is placed in the recess 430 of the second plate 420. As described above, the powder 225 can be formed of a material having a high melting point, such as the powder 225 being formed of one or more of carbon, molybdenum, and tungsten.

At block 5006, with reference to FIG. 4B, the first plate 410 is bonded with the second plate 420. In some embodiments, the first plate 410 is joined to the second plate 420 by using a sintering process. Because the first plate 410 and the second plate 420 were only partially sintered at block 5002, the plates 410, 420 can be joined together at block 5006 by completing the sintering process, for example when the plates 410, 420 are pressed together at high temperature (e.g., 2000° C.) and high pressure (e.g., >100 bar). A cavity 431 is formed between the first plate 410 and the recess 430 of the second plate 420. The powder 225 can provide structural support for the cavity 431 during the sintering process.

The sintering process performed at block 5006 forms the substrate support body 405 shown in FIG. 4C. The substrate support body 405 includes a top 401, a bottom 402, and one or more side surfaces 403 connecting the bottom 402 with the top 401.

At block 5008, with reference to FIG. 4C, a channel 406 can be machined (e.g., drilled) into the substrate support body 405. The channel 406 can extend from an opening 407 in the bottom 402 of the substrate support body 405 to the cavity 431. After the channel 406 is formed, the powder 225 can be removed (e.g., vacuumed out) from the cavity 431 through the channel 406. Alternatively, in some embodiments, the powder 225 can be burned off at a relatively low temperature, for example at atmospheric pressure, to remove the powder 225 from the cavity 431.

At block 5010, with reference to FIG. 4D, the substrate support body 405 is attached to the shaft 250. In some embodiments, the substrate support body 405 is diffusion bonded to the shaft 250.

At block 5012, with reference to FIG. 4D, the sensor 270 is positioned in the cavity 431 of the substrate support body 405. The sensor 270 can be inserted into the cavity 431 through the interior 251 of the shaft 250 and then through the channel 406 of the substrate support body 405 that connects the interior 251 of the shaft 250 to the cavity 431. The sensor 270 can include the sensing portion 271 that is positioned at location in the cavity 431 that does not overlie the interior 251 of the shaft 250. For example, the sensing portion 271 can be positioned to underlie an outer zone (e.g., edge region) of the substrate 50 (see FIG. 1) during processing. The sensor 270 can further include the one or more connectors 272 (e.g., wires) that extend through the interior 251 of the shaft 250 and electrically connect the sensing portion 271 to another device, such as a controller (not shown) that can receive measurements from the sensor 270 during processing.

While the foregoing is directed to embodiments of the present disclosure, other and further embodiments of the disclosure may be devised without departing from the basic scope thereof.

What is claimed is:

1. A substrate support assembly comprising:
a shaft; and
a substrate support comprising:
a substrate support body attached to the shaft, the substrate support body formed of a first material; and
a tube positioned inside the substrate support body, the tube formed of a second material having a melting point that is higher than a sintering temperature of the first material.

2. The substrate support assembly of claim 1, further comprising a sensor positioned inside the tube.

3. The substrate support assembly of claim 2, wherein a sensing portion of the sensor is positioned at location in an interior of the tube that does not overlie the shaft.

4. The substrate support assembly of claim 3, wherein the sensing portion of the sensor is configured to underlie an edge region of a substrate positioned on the substrate support during processing.

5. The substrate support assembly of claim 2, wherein the sensor further includes one or more connectors that extend through an interior of the shaft.

6. The substrate support assembly of claim 1, wherein the substrate support body is formed of a ceramic material and the tube is formed of molybdenum.

7. The substrate support assembly of claim 6, wherein the ceramic material is aluminum nitride.

8. A method for forming a substrate support comprising:
embedding a tube in a sintering material, an interior of the tube substantially devoid of the sintering material;
performing a sintering process on the sintering material with the tube embedded in the sintering material to form a substrate support body; and
inserting a sensor into the interior of the tube after performing the sintering process.

9. The method of claim 8, wherein the sintering material is formed of a ceramic material.

10. The method of claim 9, wherein the tube is formed a material having a higher melting point than a temperature of the sintering process performed on the sintering material.

11. The method of claim 8, wherein the sintering material is formed of aluminum nitride and the tube is formed of molybdenum.

12. The method of claim 8, further comprising attaching the substrate support body to a shaft configured to rotate the substrate support body, wherein the sensor is inserted into the tube in the substrate support body through an interior of the shaft to an interior of the tube by extending through a channel extending from an opening in a bottom side of the substrate support body to the interior of the tube.

13. The method of claim 8, wherein
a heater is embedded in the sintering material when the sintering process is performed on the sintering material, and
the sensor is a thermocouple.

14. The method of claim 8, further comprising placing a powder in the interior of the tube before performing the sintering process, wherein the powder is in the interior of the tube during the sintering process.

15. The method of claim 14, further comprising removing the powder from the tube after performing the sintering process and before inserting the sensor inside the tube, wherein the powder is formed of one or more of copper, molybdenum, or tungsten.

16. A method for forming a substrate support comprising:
forming a first plate by performing a first sintering process on a first sintering material, the first plate having a first side and an opposing second side, wherein the first sintering process partially sinters the first sintering material;
forming a second plate by performing a second sintering process on a second sintering material, the second plate having a first side and an opposing second side, wherein the second plate includes a recess on the first side and the second sintering process partially sinters the second sintering material;
placing a powder inside the recess;
positioning the first plate on top of the first side of the second plate, wherein a region between the first plate and recess of the second plate forms a cavity; and
performing a third sintering process on the first plate and the second plate to join the first plate to the second plate and form a substrate support body having a top, a bottom, and one or more sides connecting the top to the bottom, wherein the powder is formed of a material having a higher melting point than a temperature of the first plate and the second plate during the third sintering process to join the first plate to the second plate.

17. The method of claim 16, further comprising:
forming a channel extending through from an opening in the bottom of the substrate support body to the cavity; and
removing the powder from the cavity.

18. The method of claim 17, further comprising:
inserting a sensor inside the cavity through the channel; and
attaching the substrate support body to a shaft configured to rotate the substrate support body, wherein the sensor is inserted into the cavity through an interior of the shaft to the cavity by extending through a channel extending from an opening in a bottom side of the substrate support body to the cavity.

19. The method of claim 16, wherein
the first sintering material and the second sintering material are each formed of a ceramic material, and
the powder is formed of one or more of copper, molybdenum, or tungsten.

20. The method of claim 16, wherein a heater is embedded in the first sintering material when the first sintering process is performed on the first sintering material
